(19) United States
(12) Patent Application Publication
(10) Pub. No.: US 2001/0052766 A1
(43) Pub. Date: Dec. 20, 2001

(54) Apparatus for simulating electrical components

(76) Inventors: Joerg Drescher, Karlsruhe (DE); Dieter Grohmann, Gechingen (DE); Wolfgang Kull, Neuhausen (DE); Andreas Riemer, Sindelfingen (DE); Bernhard Spitzer, Hockenheim (DE)

Correspondence Address: EVENSON, McKEOWN, EDWARDS & LENAHAN, P.L.L.C., Suite 700, 1200 G Street, N.W., Washington, DC, 20005, US

(21) Appl. No.: 09/759,603

(22) Filed: Jan. 16, 2001

(30) Foreign Application Priority Data
Jan. 15, 2000 (DE) 100 01 484.4

(51) Int. Cl. G01R 1/00

(52) U.S. Cl. 324/158.1

(57) ABSTRACT

An apparatus, in particular for simulating electrical sensor/actuator components, having a drive module (4), which provides a model (5, 6, 7) of the S/A component to be simulated and generates interface signals (U₁ₙ, Uₙ) in accordance with the signals of the real S/A component to be simulated, and having a signal interface (12, 26) for each connection pin (28, 29) of the apparatus (1), which is driven by the real-time signals (8, 9, 10, 11) of the drive module (4) and generates, for each interface connection pin (28, 29), an interface signal (U₁ₙ, Uₙ) corresponding to the electrical signals of the real S/A component, in which case the current direction or the energy flow of the interface signals (U₁ₙ, Uₙ) can be directed, in a manner influenced by a control/regulation circuit of the signal interface (12, 26), towards the signal interface (12, 26) or away from the latter, with the result that the apparatus can optionally simulate a sensor or an actuator.

### BACKGROUND AND SUMMARY OF INVENTION

This application claims the priority of German Application No. 100 01 484.4, filed Jan. 15, 2000, the disclosure of which is expressly incorporated by reference herein.

The invention relates to an apparatus, in particular for simulating electrical sensor/actuator components, so-called S/A components, having a drive module, which provides a model of the S/A component to be simulated and generates real-time signals in accordance with the input or output signals of the real S/A component to be simulated, and having a signal interface for each connection pin of the apparatus, which is driven by the output signals of the drive module and generates, for each interface connection pin, an interface signal corresponding to the electrical signals of the real S/A component.

In motor vehicles, ships, aircraft, space craft, and alternatively in machine and installation controllers, referred to as target system in the description below, a large number of E/E (Electric/Electronic) components are incorporated, their complexity dictating that they must pass through various test and examination phases. In order nevertheless to keep the development times as short as possible in this case, it is necessary to already subject these E/E components to an examination when the target system, for example the motor vehicle, into which the E/E component is intended to be incorporated has not yet been constructed. On the other hand, such E/E components are also intended to be examined independently of the target system in a laboratory environment.

In connection with the examination of E/E components, at least one E/E component is connected to an apparatus for testing E/E components, which, together with the signal interface, simulates the electrical input and output signals, i.e. the interface signals to the E/E components, as are present in the real target system. In this case, the apparatus behaves like the real target system with regard to the electrical signals at the interface to the E/E component, i.e. the apparatus simulates the properties of the sensors and actuators.

DE 30 24 266 A1 discloses an apparatus for testing an E/E component, i.e. a control unit of a motor vehicle. This apparatus makes it possible to feed the sensor signals of the target system or sensor signals generated by an equivalent signal generator to the E/E component. Furthermore, it is possible to connect the loads of the target system or equivalent loads to the E/E component to be tested. This allows for checking of the function and the behaviour of the E/E component and of the entire system. Provision is made for incorporating the apparatus into the vehicle and testing the E/E components in the region of the engine.

DE 42 12 890 C2 discloses an apparatus for testing the output behaviour of an E/E component with simulated load signals being provided at the output of the E/E component. In this case, a microcomputer simulates the behaviour of an electrical valve, so that the behaviour of the E/E component, which drives the valve, can be checked, in particular upon variation of the valve states.

When such apparatuses are used together with different sensors or actuators, a new signal interface has to be developed each time for the apparatus. It is precisely when modifying the interface between the test system and the E/E component that it is necessary to modify the signal interface with altered electrical properties of the individual interface connection pins. In this case, changing the number or functionality of the E/E component pins has a particularly disadvantageous effect on the outlay for changing the apparatus.

The object of the present invention, therefore, is to develop an apparatus in such a way that different S/A components can be simulated by the apparatus with regard to the electrical input and output signals without the apparatus having to be changed or redesigned each time.

The present object is achieved by means of the features whereby the current direction of the interface signals is influenced by a control/regulation circuit of the signal interface and directed towards the signal interface or away from the latter, with the result that the apparatus can optionally simulate a sensor or an actuator.

The apparatus according to the invention has at least one modularly constructed signal interface whose interface signals, for example the current direction thereof or the energy flow at the interface connection pin, can be directed towards the signal interface, as in the case of an actuator, or away from the signal interface, as in the case of a sensor. The apparatus is preferably connected to an electrical/electronic component, so-called E/E components, via the signal interface. An E/E component might be a vehicle controller.

For this purpose, the apparatus is provided with a drive module, which provides the models of the S/A components to be simulated and/or a model for electrical fault simulation and generates real-time signals in accordance with the signals of the real S/A components to be simulated. Furthermore, the apparatus has modularly constructed signal interfaces having a specific number of signal interface modules which are driven by the output signals of the drive module and generate, for each interface connection pin, an interface signal corresponding to the electrical signals of the real S/A component.

The decisive advantage of the apparatus according to the invention is that it can optionally simulate a sensor or actuator or a plurality of actuators and sensors. To that end, the output stage and/or the control/regulation device thereof is driven in such a way that a corresponding voltage drop arises between the respective interface connection pin and the system earth, so that the current or energy flow can be established in accordance with the real conditions in S/A components.

Furthermore, electrical fault simulation is possible with the apparatus. In this case, it is possible to impress different states between signal pins or from signal pins to the supply voltage or earth. The apparatus can be used to effect both electrical fault simulation with the test system and electrical fault simulation in the target system. In addition to electrical fault simulation, the apparatus can be used as a measuring means. For this purpose, not only the simulated sensor/actuator variables but also sensor/actuator variables of real E/E components can be acquired.

The present object is also achieved by means of modular constructed apparatus, with the result that a separate signal interface is provided for each interface connection pin.

According to the invention, the apparatus is provided with at least one modularly constructed signal interface which permits E/E components to be coupled to a test system. The E/E components, for example a vehicle controller, communicate via interfaces with the inputs and/or outputs of one or more signal interfaces. As an example, supply lines, signal lines and data-exchange lines are connected to the interface. The exchanged data are preferably signals from sensors or data or signals transmitted to actuators for further active and passive S/A components. The lines must have to be driven suitably in real time via the signal interface of the apparatus, so that the signals correspond to the real conditions in the target system, for example in the motor vehicle. The sensor/actuator model which is present for each signal interface in the drive module includes the behaviour to be simulated for each individual S/A component. The signal interface connects the real E/E component, for example a controller, to the apparatus. As a result, the E/E component can be tested in a simple manner by the apparatus.

In a particularly advantageous manner, the apparatus has a printed circuit board with an insertion location for individual interface connection pins. One signal interface circuit can be inserted into each insertion location. The signal interface circuits are preferably of similar construction, with the result that the signal interface circuits allow the generation of logic signals, for example having a TTL level, for a data line. Another group of signal interface circuits is embodied in such a way that power signals, in particular for a power supply line, can be provided at the corresponding interface connection pin. Each signal interface circuit is preferably provided on a small printed circuit board or card for connection to the main printed circuit board of the apparatus. For each pin, it is possible to provide a plug-in card having a signal interface circuit which can be inserted in accordance with the number and type of pins at the interface at the insertion locations provided therefor in the main printed circuit board in the apparatus.

In a further development of the invention, a universal signal interface circuit is provided for each pin of the interface. The apparatus then has a signal interface card for each pin of an interface. The apparatus is thus equipped with a number of identical, universal signal interface cards corresponding to the number of interface pins of the connected E/E component.

The basic idea behind the apparatus is to provide a universally adaptable equivalent circuit for arbitrary sensors, actuators and electrical faults. The purpose is for the apparatus to be adapted in each case without any alteration of the hardware of the signal interface. Provision is nevertheless made for adapting the apparatus by means of different computation models to the functions and properties of the sensors, actuators or with regard to a fault simulation. In this case, the computation models are provided by software in the drive module and the signal interface circuits are driven correspondingly by the software.

One of the main advantages of the apparatus according to the invention is that uniform hardware is provided for the signal interface. The apparatus can be used universally for simulation or for examination of different E/E components. A high degree of flexibility is afforded here in the case of changes in the E/E components or in the case of using new E/E components. The adaptation of the properties of the signal interface can be carried out by simple parameterization without changing the hardware. As a result, the apparatus together with the signal interfaces can be used in the context of many technical problems and test methods and can thus be produced efficiently and cost-effectively.

Each signal interface preferably has the properties of a four-quadrant amplifier, i.e. the equivalent circuit of the sensor or actuator can both output power and receive power. The signal interface circuits provided as four-quadrant amplifiers are operated with a clocked or analog output stage. A regulating circuit, provided for each signal interface, ensures the maintenance or tracking of a set desired value at each interface connection pin. The desired values, in particular a desired voltage or a desired current, are specified by the model implemented in the drive module of the apparatus.

The electrical behaviour of the apparatus is determined by the sensor/actuator model. The model is created by means of a design tool which, for a specific sensor or an actuator, creates a mathematical model based on algebraic equations or differential equations. Modelling with active or passive functionality is provided for the sensors and actuators. An active equivalent circuit is understood to mean an electrical voltage or current source. The passive circuits may be represented by complex impedances. Specific properties of active and passive elements can be gathered from voltage and current profiles or the impedance values thereof, i.e. whether these can assume a constant or variable value or are adjustable in accordance with a discrete function.

In order to adapt the signal interface as exactly as possible to the real conditions of the S/A components, the designed model is parameterized and then verified. Since the model is implemented in software and its output signals can be adapted to the real conditions for each interface connection pin by the respective signal interface, the apparatus can use the same hardware to simulate a sensor that outputs power or an actuator that takes up power. This is possible since the output stage of each signal interface is designed as a four-quadrant amplifier. In this case, the signal levels of the sensor/actuator model are transformed into the signal levels at the interface connection pin.

A further advantage of the apparatus is that the sensor/actuator model can be provided with variation or tolerances with regard to temperature, production dimensions, moisture influences, etc. Furthermore, it is possible to model non-linearities caused for example by mechanically moving parts in the sensor or actuator. This makes it possible to achieve a much greater test spectrum and hence a significantly improved test quality.

With an apparatus including a signal generator, ammeter/voltmeter and a temperature cell, S/A components can be measured with regard to their electrical properties in a simple manner. As a result, model parameters required for the simulation of the S/A components can also be determined as a function of the temperature. The model parameters can be verified by comparing the real S/A component and the simulated S/A component.

In a particularly preferred development of the invention, the apparatus is used for fault simulation. In this case, it is possible to examine, in particular, each interface connection pin with regard to an earth fault, short circuit to the supply voltage or interruption of a line. In addition, contact or leakage resistances can be connected in between arbitrary interface connection pins. The fault simulations are realized using computation models. Real resistors or short-circuit relays are obviated. The fault simulation model interacts directly with the sensor/actuator models of the individual interface pins. As a result, it is possible to perform fault states between arbitrary interface pins or manipulations on individual interface pins.

Each apparatus preferably has an electronic protection device which triggers when overcurrents or overvoltages occur during the testing of the E/E components. The protection device is, in particular, electronically resettable, so that further testing can be effected in a convenient manner after a fault.

There are a variety of possibilities for configuring and developing the teaching of the present invention in an advantageous manner.

Other objects, advantages and novel features of the present invention will become apparent from the following detailed description of the invention when considered in conjunction with the accompanying drawings.

### BRIEF DESCRIPTION OF THE DRAWINGS

FIG. 1 shows a circuit diagram of the apparatus according to the invention, with a drive module and two signal interfaces connected thereto on the output side, and

FIG. 2 shows a circuit diagram of the apparatus according to the invention, with a fault generating means, the various fault circuitry possibilities being illustrated schematically, and

FIG. 3 shows a device for determining parameters of real S/A components as a function of the temperature, which can be used in the apparatus according to the invention.

### DETAILED DESCRIPTION OF THE DRAWINGS

The apparatus 1 for simulating electrical S/A components has a drive module 4 and two signal interfaces 12, 26. The apparatus 1 simulates a sensor, for example, which acquires specific data in the real vehicle, or an actuator which is driven by an E/E component in the real vehicle. For the sensor/actuator simulation, a sensor model 6 for the sensor or an actuator model 6, 7 for the actuator is stored in the drive module 4. The sensor/actuator models 6 and/or 7 are in each case models which are based on mathematical equations and are created by a special design tool, for example. In order to simplify the real conditions, the sensor/actuator models 6 and 7 may be composed of simpler equivalent circuits, for example current and voltage sources, complex impedances, switching devices or devices having variable parameters. In this way, for each S/A component to be simulated, a model 6 and/or 7 is stored in the drive module 4, in particular in an electronic computer.

When these models 6 and 7 are driven from a real-time computer 2, which drives the models 6 and 7 with the corresponding input variables 3 in accordance with the travelling states arising in the real vehicle, the models 6 and 7 generate and monitor the real-time signals 8, 9, 10 and 11. These real-time signals comprise control logic signals 8, desired value specification signals 9 and the actual value acquisition signals 10 and 11. The real-time signals 8, 9, 10, 11 are preferably transmitted as digital signals between the drive module 4 and the signal interfaces 12 and 26, respectively.

The signal interface 12 has, by way of example, two analog/digital converters 18, a regulating circuit 21 and an output stage comprising two transistors 22 and 23 and, if appropriate, a filter 24. Furthermore, the signal interface 12 has a digital/analogue converter 17 and a control logic arrangement 13. The present invention provides for the modular construction of the entire apparatus 1 for the simulation of S/A components for the testing of E/E components 32. To that end, the apparatus 1 has a main printed circuit board having various electrical connecting points at which a drive circuit 4 is connected to the electrical signal lines and electrical devices provided on the main printed circuit board. The modular construction of the apparatus is distinguished by the fact that from one to n identically constructed signal interface modules 12, 26 are provided, which each drive an interface connection pin 28.

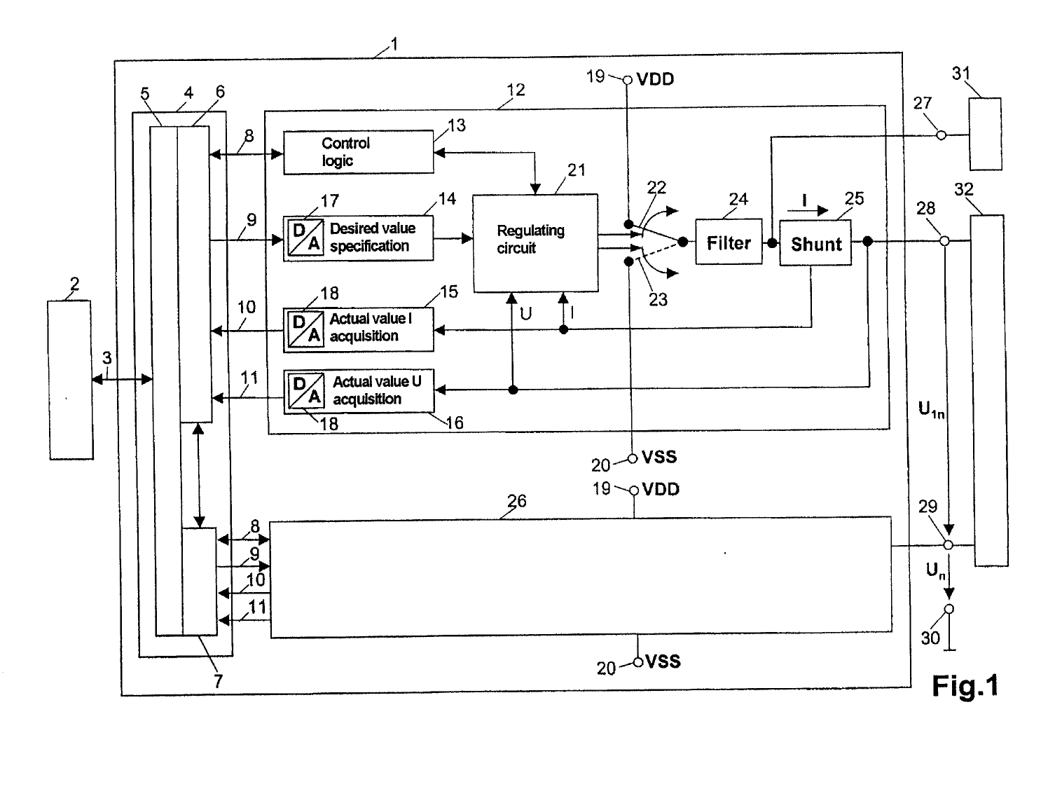

FIG. 1 shows the apparatus 1 with the drive module 4 of the first signal interface circuit 12 and of an nth signal interface circuit 26. Each signal interface 12, 26 has a control logic arrangement 13 for setting the operating mode, two analog/digital converters 18 and, as the output stage, a four-quadrant amplifier comprising the switching transistors 22 and 23. Furthermore, a regulating circuit 21 on the circuit board of the signal interface 12 and a filter 24 are additionally provided. The output stage comprising the switching transistors 22 and 23 and the filter 24 are designed in such a way that they can both output power and receive power.

The two switching transistors 22 and 23 switch for example with respect to a positive supply voltage V_{DD} 19 and a negative supply voltage V_{SS} 20. As a result, it is possible to generate positive and negative output voltages and output currents at the connection pin 28. Depending on the switching state of the output stage, it is possible to generate a voltage drop between the interface connection pin 28 and the system earth 30, or vice versa, which generates the desired current or power flow. The filter 24 serves to smooth the output voltage Uₙ or the output current I. The shunt 25 measures the current via the interface connection pin 28. The measured current is fed to the regulating circuit 21 and to the actual value acquisition arrangement 15 for the current via the analog/digital converter 18. Likewise, the output voltage U₁ at the connection pin 28 is measured and fed to the regulating circuit 21 and to the actual value acquisition arrangement 16 for the voltage via the other analog/digital converter 18.

In the regulating circuit 21, with the actual-value variable voltage U, the actual-value variable current I and the desired value specification, the drive signals for the switching transistors 22 and 23 are generated in a suitable way by means of a PID regulator with two pulse width modulators connected downstream. It is particularly advantageous for the switching transistor 22 to be driven by means of a first pulse width modulation and for the switching transistor 23 to be driven by means of a second pulse width modulation. By virtue of the first pulse width modulation being fixedly linked temporally with the second pulse width modulation, an optimum regulation behaviour is achieved in the zero region of the output voltage U and of the output current I. Both the measured current I and the measured voltage U are reported back to the model 6 in the drive module 4 again via the feedback actual-value interfaces 10 and 11, with the result that the output voltage—provided by the model 6—at the signal interface connection pin 28 can be adjusted by the regulating circuit 21. The desired value specification 14 is made available to the regulating circuit 21 once again by the model 6 via the digital/analogue converter 17.

In addition to the signal interface 12, FIG. 1 shows an nth signal interface 26, which is driven in the same way by the drive circuit 4 by means of a model 7. At the interface connection pin 29, the signal interface 26 generates the output voltage Uₙ relative to the system earth 30. This arrangement can be used to obtain any desired differential voltages U₁ₙ by interaction of the models 6 and 7. This is particularly advantageous for apparently potential-free simulations, such as non-reactive resistances for example.

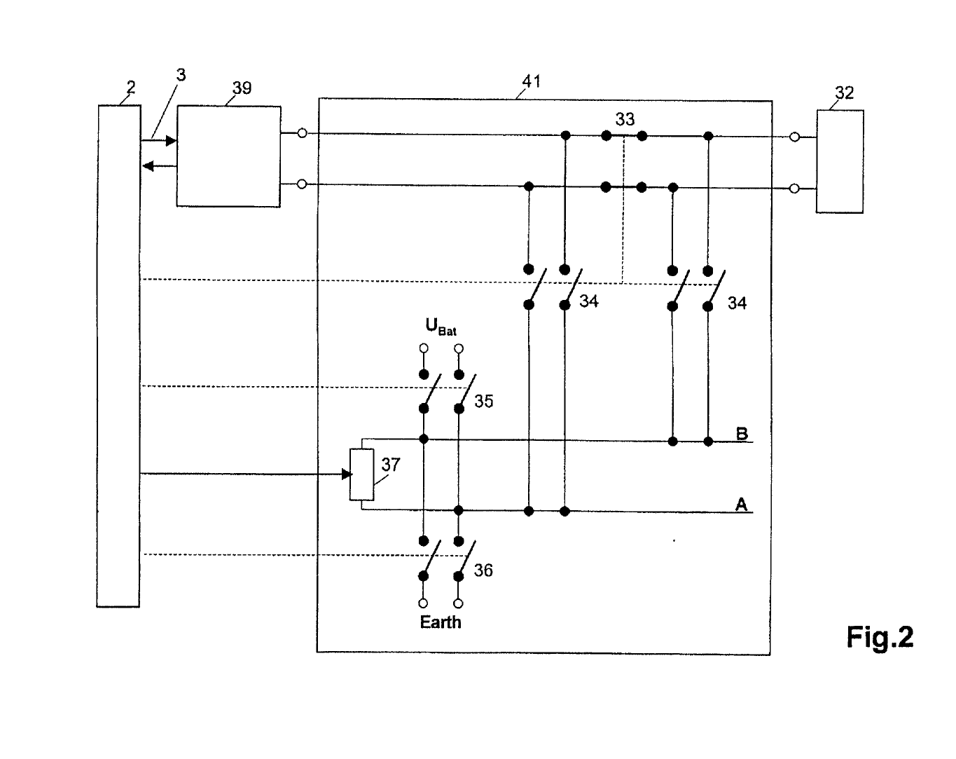

FIG. 2 schematically illustrates what faults can be implemented in a fault simulation device 41, which is connected to the real-time computer 2 via an electrical signal adapting arrangement 39. The fault simulation device 41 can provide a short circuit 36 to earth, a short circuit 35 to a line with supply voltage, a line interruption 33 or, connected in between the collective lines A and B, controllable sources, sinks or a measuring instrument 37. The switches 34 serve to produce the connection of the E/E components 32 to the collective lines A and B. The faults can be switched on on the fault simulation device 41 by the real-time model input variables 3 from the real-time computer 2.

According to the invention, a separate fault simulation device 41, by means of switches or the like, can be completely obviated owing to the fault simulation model 5. The fault simulation model 5 is preferably integrated in the drive circuit 4 as a superordinate mathematical model. Short circuits are modelled by a corresponding voltage difference U₁ₙ of 0 volts. Interruptions are generated by a current I of 0 amperes. The controllable source/sink 37 can likewise be embodied in a highly universal fashion using corresponding mathematical models.

The apparatus 1 can also measure a real S/A component 31 which is connected to the connection pin 27 of the signal interface 12. In this case, the voltage and current variables can be measured with the existing circuit of the signal interface 12. Stimuli signals can be applied to the S/A component via the output stage 22, 23, 24, in order to measure a signal step response, for example. The parameters obtained from this are used for the sensor/actuator model 6.

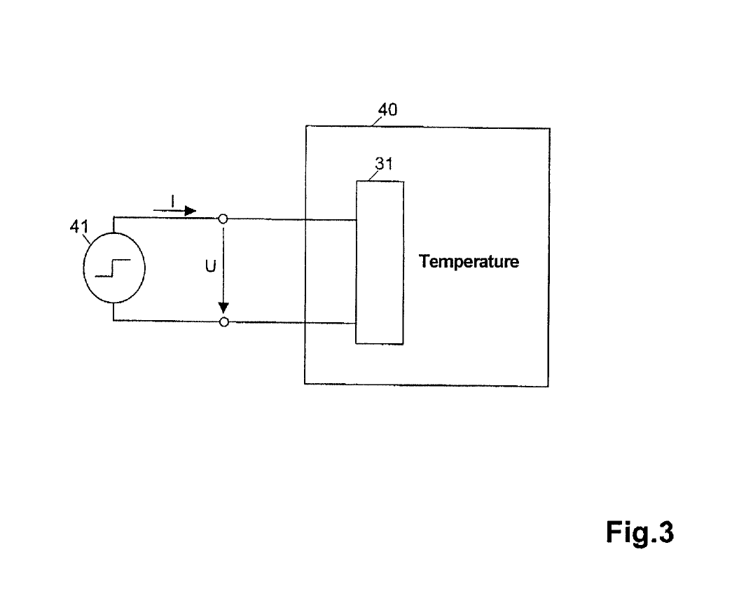

As an alternative, the external device shown in FIG. 3 can be used for measuring a real S/A component 31 with a signal generator 40 at different temperatures. The temperature is set by means of a temperature cell 39.

The apparatus 1 can advantageously be used for electrical fault simulation by being incorporated into the target system. In this case, a real S/A component is connected to the connection pin 27. The E/E component 32 is connected to the connection pin 28. By means of the output stage 22, 23, 24, fault simulation signals generated by means of the fault simulation model 5 can be connected to the connection of S/A components 31 and E/E components 32.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed:

1. An apparatus for simulating an electrical sensor/actuator component, comprising:
a drive module including a model of the sensor/actuator component, said drive module generating interface signals in accordance with signals of said sensor/actuator component being simulated, said drive module further including at least one signal interface with each one of said at least one signal interface being associated with a respective connection pin which is driven by real-time signals from said drive module and wherein said at least one signal interface generates, for each said interface connection pin, one of said interface signals corresponding to the electrical signals of said sensor/actuator component;
wherein each of said at least one signal interface includes a control/regulation circuit for directing current or energy of said generated interface signals in a direction either towards said at least one signal interface or away from said at least one signal interface whereby a sensor or an actuator can be optionally simulated.

2. An apparatus for simulating an electrical sensor/actuator component, comprising:
a drive module including a model of the sensor/actuator component, said drive module generating interface signals in accordance with signals of said sensor/actuator component being simulated, said drive module further including at least one signal interface with each one of said at least one signal interface being associated with a respective connection pin which is driven by a real-time signals from said drive module and wherein said at least one signal interface generates, for each said interface connection pin, one of said an interface signals corresponding to the electrical signals of said sensor/actuator component;
wherein said apparatus includes modular construction in order to provide a separate signal interface for each interface component.

3. The apparatus according to claim 1, wherein said drive module further includes means for calculating mathematical modules for driving said at least one signal interface and wherein said module generates said real-time signals in order to obtain said interface signals in accordance with the simulated sensor/actuator components at the interface connection pins.

4. The apparatus according to claim 1, further including a main printed circuit board having one insertion location for each interface connection for each of said interface pins and wherein one of said signal interfaces is provided for each insertion location.

5. The apparatus according to claim 1, wherein each of said signal interfaces has an output stage.

6. The apparatus according to claim 5, wherein said output stage is a four-quadrant amplifier, which can function to output power or to receive power.

7. The apparatus according to claim 1, wherein said drive module comprises a computer for providing an equivalent circuit of the sensor/actuator component as said model.

8. The apparatus according to claim 1, wherein said model of said drive module is adapted to signals required at an interface connection pin by utilizing specific parameters.

9. The apparatus according to claim 1, further comprising a fault simulation module for generating one of a line interruption and a short circuit.

10. The apparatus according to claim 1, wherein each of said signal interfaces has a regulating circuit for adjusting one of voltage and current to a value specified by said model.

11. The apparatus according to claim 10, wherein said regulating circuit includes a feedback arrangement to the drive module in order to provide actual values of regulated variables to said model.

12. The apparatus according to claim 10, further including, a subordinate regulating loop which drives said output stage in order to achieve fast regulation of regulated variables.

13. The apparatus according to claim 2, wherein said drive module further includes means for calculating mathematical modules for driving said at least one signal interface and wherein said module generates said real-time signals in order to obtain said interface signals in accordance with the simulated sensor/actuator components at the interface connection pins.

14. The apparatus according to claim 2, further including a main printed circuit board having one insertion location for each interface connection for each of said interface pins and wherein one of said signal interfaces is provided for each insertion location.

15. The apparatus according to claim 2, wherein each of said signal interfaces has an output stage.

16. The apparatus according to claim 2, wherein said output stage is a four-quadrant amplifier, which can function to output power or to receive power.

17. The apparatus according to claim 2, wherein said drive module comprises a computer for providing an equivalent circuit of the sensor/actuator component as said model.

18. The apparatus according to claim 2, wherein said model of said drive module is adapted to signals required at an interface connection pin by utilizing specific parameters.

19. The apparatus according to claim 2, further comprising a fault simulation module for generating one of a line interruption and a short circuit.

20. The apparatus according to claim 2, wherein each of said signal interfaces has a regulating circuit for adjusting one of voltage and current to a value specified by said model.
